(19) United States
(12) Patent Application Publication
(10) Pub. No.: US 2009/0122494 A1
(43) Pub. Date: May 14, 2009

(54) Cooling Device for Printed Circuit Board and Method for the Prosecution Thereof

(75) Inventors: Josef Schmidt, Ingolstadt (DE); Peter Weichselbaumer, Augsburg (DE); Dirk Riese, Nurnberg (DE)

Correspondence Address: CONTINENTAL TEVES, INC., ONE CONTINENTAL DRIVE, AUBURN HILLLS, MI, 48326-1581, US

(73) Assignee: Conti Temic Microelectronic GMBH

(21) Appl. No.: 11/918,075

(22) PCT Filed: Feb. 18, 2006
(86) PCT No.: PCT/DE2006/000305

§ 371 Date: Oct. 9, 2007

(30) Foreign Application Priority Data
Apr. 6, 2005 (DE) 10 2005 015 749.1

(51) Int. Cl. H05K 7/20; H05K 3/00

(52) U.S. Cl. 361/720; 29/829

(57) ABSTRACT

Disclosed is a cooling device (1) for a printed circuit board (2) which is disposed in a housing (3) and can be connected in a locking manner to a metal cooling element (4) that is formed as a cover of said housing (3).

### BACKGROUND OF THE INVENTION

The invention relates to a cooling device for a printed circuit board which is disposed in a housing and to a method for the production of such cooling device.

With electronic control devices, in particular in the automotive industry, frequently a printed circuit board equipped with electronic components is enclosed in a plastic housing. The electronic components usually produce a power loss, which in the form of waste heat leads to a heating of the assembly group. It is a problem to transport this waste heat outwards out of the housing and to deliver it to the environment to avoid an overheating of the assembly group.

An effective possibility known from prior art to produce a thermally conducting connection between the printed circuit board in the housing and the environment is to glue the printed circuit board with the aid of a heat conducting foil onto a metal plate, preferably made of aluminum, and to subsequently screw it with the housing. With this concept the metal plate serves as a cooling element and simultaneously as a cover of the housing. By default this mounting technics is used with many control devices in the automotive industry.

A disadvantage of this mounting technics is that for maintaining a good thermal connection between printed circuit board and metal cooling element always a certain contact pressure must be available. For this purpose a screw connection of the metal cooling element to the plastic housing is necessary.

It is the object of the invention to indicate an improved cooling device of the type initially specified which can be produced at small expenditure.

### SUMMARY OF THE INVENTION

This object is achieved according to invention by a cooling device, for a printed circuit board (2) disposed in a housing (3), which is connected in locking manner to a metal cooling element (4), which is formed as a cover of the housing (3). The object is also achieved by a method for the production of a cooling device (1), wherein a printed circuit board (2) disposed in a housing (3) is provided with a heat conducting body (7) of a flowable heat conducing material and that a metal cooling element (4) is connected in locking or snatching manner to the housing (3) by contacting the heat conducting body (7), before the heat conducting material is completely hardened.

The invention provides a cooling device, wherein the printed circuit board can be connected to a metal cooling element, which is formed as a cover of the housing and which can be connected in a locking or snatching manner to it. By this screwless and detachable connection a complex screw connection is safely avoided. This reduces both the number of used parts and the assembly expenditure.

In a preferred embodiment the housing comprises at least one detent hook for locking and/or snatching of the metal cooling element at the housing. The detent hook represents a simple means for a screwless connection, in particular a simple locking or snatching connection.

For compensating manufacturing tolerances, e.g. of the thickness of the printed circuit board or of the cover, at least one spring element is provided, which enables a defined position of the metal cooling element in relation to the printed circuit board and the housing. Here, the spring element provides that the metal cooling element is impacted by compressive stress in the locked and/or snatched condition. In a special embodiment the compressive stress is directed against an undercut of the detent hook. Tensioning of the printed circuit board by different lines of force is excluded by this.

Preferably, the spring element consists of a part of the housing. For example the spring elements are formed as housing lips to the housing formed for example of plastics. In this manner no additional parts and no additional assembly expenditure are necessary.

A preferred form of embodiment provides that a heat conducting body is arranged between the printed circuit board and the metal cooling element. In this way the printed circuit board can be distanced from the metal cooling element, so that for example constructional systems such as electronic components on the printed circuit board are possible.

Advantageously, the heat conducting body is formed of an originally flowable, hardened heat conducting material, in particular of a heat conducting mass. Flowable heat conducting materials, for example heat-conductive pastes, are available from different manufacturers, which after hardening stick together with the substrate and therefore do not require any contact pressure. Such a flowable heat conducting mass allows for the compensation of distance tolerances between the printed circuit board and the metal cooling element.

Appropriately, the housing is made of plastics. This allows for a small weight and a simple production of the housing. Besides, electrical problems such as short-circuits by the insulator effect of plastics are avoided.

A defined positioning of the printed circuit board in the housing succeeds by at least one rest for the printed circuit board within the housing. The rest is formed in type of a rest dome and can be formed to the housing. Several rest domes for positioning the printed circuit board can be provided in the housing. The housing can also be formed as a prefabricated module, which is produced as a plastic module in a pressure or forming process together with the rest domes and the housing lips formed as spring elements.

The method according to invention for the production of a cooling device provides that a printed circuit board disposed in a housing is provided with a flowable heat conducting body made of a heat conducing material and that a metal cooling element is connected in locking or snatching manner to the housing by contacting the heat conducting body, before the heat conducting material is completely hardened.

In a preferred form of embodiment, thereby a heat conducting mass with high viscosity is used as heat conducting material. In this way the heat conducting mass is displaceable by pressure without running liquid.

The essential feature of the invention is the mechanism to compensate tolerances. The advantages achieved with the invention are in particular that the metal cover can be fixed in screwless manner and, while using a flowable heat conducting material, nevertheless a durable, thermally conductive connection between printed circuit board and metal cover can be attained.

### BRIEF DESCRIPTION OF THE DRAWINGS

Examples of embodiment of the invention will be described in the following on the basis of Figures, which show:

FIG. 1 a first variant of a cooling device and

FIG. 2 a second variant of a cooling device.

### DETAILED DESCRIPTION OF THE DRAWINGS

According elements are provided with like reference numerals in all Figures.

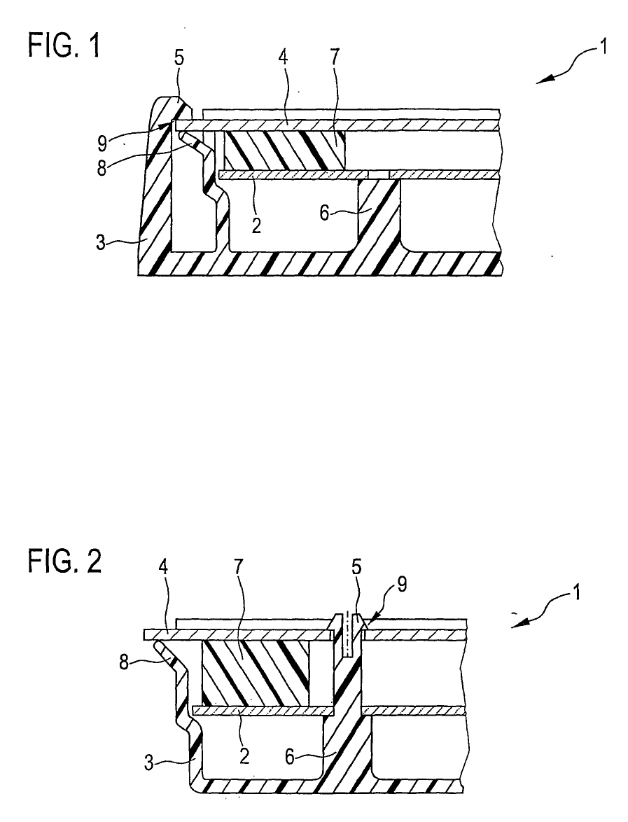

FIG. 1 shows a section of a cooling device 1 for a printed circuit board 2, which is disposed in a plastic housing 3. A metal cooling element 4 in form of plates is provided as a cover for the housing 3. According to invention the metal cooling element 4 is not screwed with the plastic housing, but is fixed by a snatching detent hook 5. Depending upon size and form of the printed circuit board 2 several detent hooks 5 or a detent edge circulating at the housing edge can be provided. In FIG. 1 a detent hook 5 is exemplified.

In the housing 3 the printed circuit board 2 rests on a level which is defined for example by a rest 6, which is embodied as a dome. Several rests 6 can be provided for positioning the printed circuit board 2 in the housing 3.

The space between the metal cooling element 4 and the printed circuit board 2 is filled out with a flowable heat conducting material, which hardens after assembly to a heat conducting body 7 and thus effects a durable thermally conductive connection. In an alternative embodiment for example a firm heat conducting body can be used between printed circuit board 2 and metal cooling element 4.

If it was be possible, to manufacture the housing 3, the printed circuit board 2 and the metal cooling element 4 without tolerances, then the length of the detent hooks 5 could be interpreted in such a way that always the minimum possible distance between printed circuit board 2 and the metal cooling element 4 is realized. The minimum distance can be given for example by the size of the firm fillers present in the heat conducting body 7 and by the thickness of a firm heat conducting body 7, respectively. However, all components of the assembly group are subject to tolerances caused by production, in particular the length of the detent hooks 5, the thickness of the metal cooling element 4 and the thickness of the printed circuit board 2. If one interprets the detent hooks 5 in such a way that with tolerance-caused maximum thickness of the metal cooling element 4 and maximum thickness of the printed circuit board 2 the distance between printed circuit board 2 and metal cooling element 4 becomes minimal, then after the assembly a play between detent hook 5 and metal cooling element 4 would result in the reverse case, i.e. with a minimum thickness of the printed circuit board 2 and the metal cooling element 4. The metal cooling element 4 would thus be not sufficiently fixed.

In order to avoid the described problem, which results as a consequence of the manufacturing tolerances, which can be hardly avoided, of the parts of the assembly group, a defined position for the metal cooling element 4 is created by means of a combination of detent hook 5 and spring elements 8. In this example a special design of the housing 3 serves for compensating the manufacturing tolerances of the housing 3, the printed circuit board 2 and the metal cooling element 4. The spring elements 8 are formed as housing lips inside the housing 3 in one piece with it and made of plastics. They press the metal cooling element 4 against the undercuts 9 of the detent hooks 5. Thereby, they form defined bearing surfaces for the metal cooling element 4. In an alternative arrangement the spring elements 8 can be inserted as separate parts into the housing 3.

The arrangement of the spring elements 8 leads to the fact that both the printed circuit board 2 and the metal cooling element 4 always rest on a defined level. The manufacturing tolerances in the thicknesses of the printed circuit board 2 and the metal cooling element 4 as well as of the length of the detent hooks 5 thus result only to a variation of the distance between printed circuit board 2 and metal cooling element 4, which is bridged by the flowable heat conducting material or by the heat conducting body 7 formed from it, respectively. After the snatching of the metal cooling element 4 the distance remains constant, so that the hardening heat conducting mass comprises a constant form.

The quantity of the flowable heat conducting material, which is to be applied onto the printed circuit board 2 before assembly of the metal cooling element 4 is to be selected in such a way that the maximum distance, created while utilizing the manufacturing tolerances, between printed circuit board 2 and metal cooling element 4, is still safely bridged. Since the material is flowable during assembly, the material surplus is laterally displaced with a smaller than the maximum distance.

The non full-scale illustration shows as an example a possible variant of an embodiment, in which the housing lip is formed as a spring element 8 in such manner that during assembly of the metal cooling element 4 it is deflected as a cover in the entire range of tolerance and thus always exerts a reset force onto the metal cooling element 4. It presses the metal cooling element 4 against the undercut 9 of the detent hooks 5. Thus, the position of the metal cooling element 4 is defined. The position of the printed circuit board 2 is defined by a rest 6 formed at the plastic housing 3. The space created between the metal cooling element 4 and the printed circuit board 2 is bridged by the flowable heat conducting material, which hardens after the assembly, a thermally conducting connection being created via the heat conducting body 7 created in this way.

In FIG. 2 a further form of embodiment of a cooling device 1 is shown in the section, in which the spring elements 8 are formed as housing lips located outside the housing 3 being embodied in one piece with the housing 3 made of plastics. A detent hook 5 sits in the middle range of the metal cooling element 4. The detent hook 5 is arranged in the region of a rest 6 of the housing 3 and is embodied in one piece with the housing 3 and made of plastics. Alternatively, the detent hook 5 can be inserted into the housing 3 for example also as a separate part on the rest 6. In this case the printed circuit board 2 and the metal cooling element 4 comprise recesses, through which the detent hook 5 can protrude. Around the detent hook 5 in a defined situation the printed circuit board 2 rests on the rest 6 and at an intermediate edge of the housing 3.

### LIST OF REFERENCE NUMERALS

1 Cooling device

2 Printed circuit board

3 Housing

4 Metal cooling element

5 Detent hook

6 Rest

7 Heat conducting body

8 Spring element

9 Undercut

1-11. (canceled)

12. A cooling device (1) for a printed circuit board (2) disposed in a housing (3), which is connected in locking manner to a metal cooling element (4), which is formed as a cover of the housing (3).

13. The cooling device of claim 12, wherein the housing (3) of the metal cooling element (4) comprises at least one detent hook (5).

14. The cooling device of claim 12, wherein at least one spring element (8) is provided, which impacts the metal cooling element (4) in the locked position by compressive stress.

15. The cooling device of claim 14, wherein the spring element (8) is formed from a part of the housing (3).

16. The cooling device of claim 14, wherein compressive stress is directed against an undercut (9) of the detent hook (5).

17. The cooling device of claim 12, wherein a heat conducting body is arranged between the printed circuit board (2) and the metal cooling element (4).

18. The cooling device of claim 17, wherein the heat conducting body (7) is formed from an originally flowable, hardened heat conducting material.

19. The cooling device of claim 12, wherein the housing (3) is made of plastic.

20. The cooling device of claim 12, wherein the housing (3) comprises at least one rest (6) for the printed circuit board (2).

21. A method for producing a cooling device (1), the method comprising:
providing a printed circuit board (2) disposed in a housing (3) having a heat conducting body (7) of a flowable heat conducing material and that a metal cooling element (4) is connected in locking or snatching manner to the housing (3) by contacting the heat conducting body (7), before the heat conducting material is completely hardened.
